(19) United States
(12) Patent Application Publication
(10) Pub. No.: US 2022/0334474 A1
(43) Pub. Date: Oct. 20, 2022

(54) PHOTORESIST COMPOSITION AND METHOD OF FABRICATING SEMICONDUCTOR DEVICE

(71) Applicant: SAMSUNG ELECTRONICS CO., LTD., Suwon-si (KR)

(72) Inventors: Hongjoon LEE, Suwon-si (KR); Sungan DO, Hwaseong-si (KR); Sukkoo HONG, Suwon-si (KR); Seongji KWON, Seoul (KR); Jonghoon KIM, Suwon-si (KR); Sooyoung KIM, Seongnam-si (KR); Jaehee CHOI, Hwaseong-si (KR)

(21) Appl. No.: 17/721,852

(22) Filed: Apr. 15, 2022

(30) Foreign Application Priority Data
Apr. 16, 2021 (KR) 10-2021-0050090
Jan. 13, 2022 (KR) 10-2022-0005333

(51) Int. Cl. G03F 7/004; G03F 7/038

(52) U.S. Cl. CPC G03F 7/0042; G03F 7/0382; G03F 7/0045

(57) ABSTRACT

A photoresist composition and a method of fabricating a semiconductor device, the composition including a photosensitive polymer having a protecting group; a photoacid generator (PAG); a metal precursor, the metal precursor being capable of generating metal ions and secondary electrons in response to irradiating light of a 13.5 nm wavelength thereto; and a solvent.

### CROSS-REFERENCE TO RELATED APPLICATIONS

This application is based on and claims priority under 35 U.S.C. § 119 to Korean Patent Application Nos. 10-2021-0050090, filed on Apr. 16, 2021, and 10-2022-0005333, filed on Jan. 13, 2022, in the Korean Intellectual Property Office, the disclosures of which are incorporated by reference herein in their entirety.

### BACKGROUND

### 1. Field

Embodiments relate to a photoresist composition and a method of fabricating the semiconductor device.

### 2. Description of the Related Art

Due to the development of electronic technology, the down-scaling of semiconductor devices has been performed at a rapid pace. Accordingly, a photolithography process that is advantageous for implementing a fine pattern may be used.

### SUMMARY

The embodiments may be realized by providing a photoresist composition including a photosensitive polymer having a protecting group; a photoacid generator (PAG); a metal precursor, the metal precursor being capable of generating metal ions and secondary electrons in response to irradiating light of a 13.5 nm wavelength thereto; and a solvent.

The embodiments may be realized by providing a photoresist composition including a photosensitive polymer having a protecting group; a photoacid generator (PAG) that generates acid in response to irradiating light of a 13.5 nm wavelength thereto; a metal precursor having a structure of Chemical Formula (I); and a solvent,

MₙLₘ (I),

wherein, in Chemical Formula (I), M is a metal element having an atomic absorption cross section of 5×10⁶ cm²/mole or more with respect to irradiation of light of a 13.5 nm wavelength, L is halogen, an alkyl group having a carbon number of 1 to 12, an alkenyl group having a carbon number of 2 to 12, an alkynyl group having a carbon number of 2 to 12, an alkoxy group having a carbon number of 1 to 12, a cycloalkyl group having a carbon number of 3 to 15, an aryl group having a carbon number of 6 to 20, an aryloxy group having a carbon number of 6 to 20, an allyl group having a carbon number of 3 to 15, a carboxylate group having a carbon number of 2 to 20, or a (meth)acrylate group having a carbon number of 2 to 20, n is an integer of 1 to 12, and m is an integer of 2 to 72 such that m=2n to 6n.

The embodiments may be realized by providing a photoresist composition including a photosensitive polymer; a photoacid generator; a metal precursor, the metal precursor including tin (II) ethoxide, tin (IV) n-butoxide, tin (IV) tert-butoxide, tin (IV) acetate, tin (II) 2-ethylhexanoate, dibutyl tin chloride, lead (II) acetate hydrate, zinc acetate hydrate, or titanium (IV) isopropoxide; a basic quencher; and a solvent.

The embodiments may be realized by providing a method of fabricating a semiconductor device, the method including forming a photoresist material layer on a lower film by using a photoresist composition; performing a first bake on the photoresist material layer; performing an exposure operation by irradiating a KrF excimer laser (248 nm wavelength), an ArF excimer laser (193 nm wavelength), an F₂ excimer laser (157 nm wavelength), or an EUV light (13.5 nm wavelength) to a partial area of the photoresist material layer on which the first bake has been performed; performing a second bake on the photoresist material layer after irradiating the partial area of the photoresist material layer; removing an unexposed portion of the photoresist material layer on which the second bake has been performed to form a photoresist pattern; and processing the lower film by using the photoresist pattern, wherein the photoresist composition includes a photosensitive polymer having a protecting group; a photoacid generator; a metal precursor capable of generating metal ions and secondary electrons in response to irradiating light thereon; and a solvent.

### BRIEF DESCRIPTION OF THE DRAWINGS

Features will be apparent to those of skill in the art by describing in detail exemplary embodiments with reference to the attached drawings in which:

FIG. 1 is a conceptual view schematically showing a mechanism of a photoresist composition according to an embodiment being cured by exposure and post exposure bake (PEB);

FIG. 2 is a flowchart of a method of fabricating an integrated circuit device, according to embodiments;

FIGS. 3A to 3E are cross-sectional views of stages in a method of fabricating an integrated circuit device, according to embodiments;

FIGS. 4A and 4B are schematic views of extreme ultraviolet (EUV) exposure performed on a photoresist film on a feature layer;

FIG. 5 is a schematic view showing an exemplary process for cross-linking a photosensitive polymer by using a metal precursor; and

FIG. 6 is a graph showing a ratio of a remaining film for each exposure dose after patterning using photoresist compositions of Example 1 and Comparative Example 1.

### DETAILED DESCRIPTION

A photoresist composition according to an embodiment may include, e.g., a photosensitive polymer, a photoacid generator (PAG), a metal precursor, and a solvent.

Photosensitive Polymer

The photosensitive polymer may be a polymer capable of causing or undergoing a photochemical reaction by or in response to irradiation of a KrF excimer laser (248 nm wavelength), an ArF excimer laser (193 nm wavelength), an F₂ excimer laser (157 nm wavelength), or an extreme ultraviolet (EUV) light (13.5 nm wavelength) thereon, e.g., irradiation of EUV light.

In an implementation, the photosensitive polymer may have an increased solubility to a developer by or in response to the photochemical reaction. In an implementation, the photosensitive polymer may have a protecting group bonded to a repeating unit, and the protecting group may be an acid-labile functional group. The protecting group may be deprotected by acid generated in or during an exposure operation so that the photosensitive polymer may be well dissolved in a developer. In an implementation, the deprotected protecting group may generate new acid to perform chemical amplification.

(Polyhydroxystyrene Resin)

In an implementation, the photosensitive polymer may be a polyhydroxystyrene (PHS) resin. In an implementation, the PHS resin may be resin having a repeating unit represented by Chemical Formula 1.

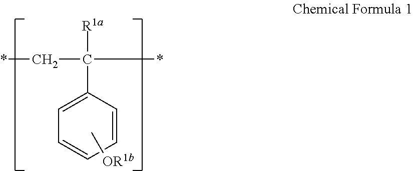

In Chemical Formula 1, R^{1a} may be or may include, e.g., a hydrogen atom or an alkyl group having a carbon number of 1 to 6. R^{1b} may be, e.g., an acid-dissociable protecting group. In an implementation, the protecting group may include, e.g., a straight-chain, branched-chain, or closed-chain (e.g., cyclic) alkyl group having a carbon number of 1 to 6, a vinyloxyethyl group, tetrahydropyranyl group, tetrafuranyl group, trialkylsilyl group, isonobonyl group, 2-methyl-2-adamantyl group, 2-ethyl-2-adamantyl group, 3-tetrahydrofuranyl group, 3-oxocyclohexyl group, γ-butyllactone-3-yl group, mavaloniclactone group, γ-butyrolactone-2-yl group, 3-methyl-γ-butyrolactone-3-yl group, 2-tetrahydropyranyl group, 2-tetrahydrofuranyl group, 2,3-propylene carbonate-1-yl group, 1-methoxyethyl group, 1-ethoxyethyl group, 1-(2-methoxyethoxy)ethyl group, 1-(2-acetoxyethoxy)ethyl group, t-buthoxycarbonylmethyl group, methoxymethyl group, ethoxymethyl group, trimethoxysilyl group, triethoxysilyl group, methoxyethyl group, ethoxyethyl group, n-propoxyethyl group, isopropoxyethyl group, n-butoxyethyl group, isobutoxyethyl group, tert-butoxyethyl group, cyclohexyloxyethyl group, methoxypropyl group, ethoxypropyl group, 1-methoxy-1-methyl-ethyl group, 1-ethoxy-1-methylethyl group, tert-butoxycarbonyl (t-BOC), or tert-butoxycarbonylmethyl group. In an implementation, the straight-chain or branched-chain alkyl group may include, e.g., a methyl group, an ethyl group, a propyl group, an isopropyl group, an n-butyl group, an isobutyl group, a tert-butyl group, a pentyl group, isopentyl group, neopentyl group, or the like. In an implementation, the closed-chain alkyl group may include, e.g., a cyclopentyl group, a cyclohexyl group, or the like. As used herein, the term “or” is not an exclusive term, e.g., “A or B” would include A, B, or A and B.

In an implementation, the PHS resin may further include other repeating units. In an implementation, the other repeating units may be repeating units of, e.g., monocarboxylic acids such as acrylic acid, methacrylic acid, crotonic acid, or the like; dicarboxylic acids such as maleic acid, fumaric acid, itaconic acid, or the like; methacrylic acid derivatives having a carboxyl group and an ester bond such as 2-methacryloyl oxyethylsuccinic acid, 2-methacryloyl oxyethylmaleic acid, 2-methacryloyl oxyethylphthalic acid, 2-methacryloyl oxyethylhexahydrophthalic acid, or the like; (meth)acrylic acid alkyl esters such as methyl(meth)acrylate, ethyl(meth)acrylate, butyl(meth)acrylate, or the like; (meth)acrylic acid hydroxyalkyl esters such as 2-hydroxyethyl(meth)acrylate, 2-hydroxypropyl(meth)acrylate, or the like; (meth)acrylic acid aryl esters such as phenyl(meth)acrylate, benzyl(meth)acrylate, or the like; dicarboxylic acid diesters such as maleic acid diethyl, fumaric acid dibutyl, or the like; aromatic compounds containing a vinyl group such as styrene, α-methylstyrene, chlorostyrene, chloromethylstyrene, vinyltoluene, hydroxystyrene, α-methylhydroxystyrene, α-ethylhydroxystyrene, or the like; aliphatic compounds containing a vinyl group such as acetic acid vinyl or the like; conjugated diolefins such as butadiene, isoprene, or the like; polymerizable compounds containing a nitrile group such as acryllonitrile, methacrylonitrile, or the like; polymerizable compounds containing chloride such as vinyl chloride, vinylidene chloride, or the like; polymerizable compounds containing an amide bond such as acrylamide, methacrylic amide, or the lik.

(Acryl Resin)

In an implementation, the photosensitive polymer may be an acryl resin. In an implementation, the acryl resin may be resin having a repeating unit represented by Chemical Formula 2.

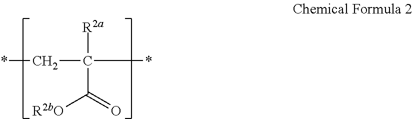

In Chemical Formula 2, R^{2a} may be or include, e.g., a hydrogen atom, a straight-chain or branched-chain alkyl group having a carbon number of 1 to 6, a fluorine atom, or a straight-chain or branched-chain fluorine alkyl group having a carbon number of 1 to 6. R^{2b} may be an acid-dissociable protecting group, e.g., as described above in relation with Chemical Formula 1.

In an implementation, the photosensitive polymer may include, e.g., a (meth)acrylate polymer. The (meth)acrylate polymer may include, e.g., an aliphatic (meth)acrylate polymer, and may include, e.g., binary or ternary copolymers of repeating units of polymethylmethacrylate (PMMA), poly(t-butylmethacrylate), poly(methacrylic acid), poly(norbornylmethacrylate), (meth)acrylate-based polymers, or a combination thereof.

In an implementation, the acryl resin may further include other repeating units. The other repeating units may be repeating units of, e.g., acrylates with ether bonds such as 2-methoxyethyl(meth)acrylate, 2-ethoxyethyl(meth)acrylate, methoxytriethylene glycol (meth)acrylate, 3-methoxybutyl(meth)acrylate, ethylcarbitol(meth)acrylate, phenoxypolyethylene glycol (meth)acrylate, methoxypolyethylene glycol (meth)acrylate, methoxypolypropylene glycol (meth)acrylate, tetrahydrofurfuril (meth)acrylate, or the like; monocarboxylic acids such as acrylic acid, methacrylic acid, crotonic acid, or the like; dicarboxylic acids such as maleic acid, fumaric acid, itaconic acid, or the like; methacrylic acid derivatives having a carboxyl group and an ester bond such as 2-methacryloyl oxyethylsuccinic acid, 2-methacryloyl oxyethylmaleic acid, 2-methacryloyl oxyethylphthalic acid, 2-methacryloyl oxyethylhexahydrophthalic acid, or the like; (meth)acrylic acid alkyl esters methyl(meth)acrylate, ethyl(meth)acrylate, butyl(meth)acrylate, cyclohexyl(meth)acrylate, or the like; (meth)acrylic acid hydroxyalkyl esters such as 2-hydroxyethyl(meth)acrylate, 2-hydroxypropyl(meth)acrylate, or the like; (meth)acrylic acid aryl esters such as phenyl(meth)acrylate, benzyl(meth)acrylate, or the like; dicarboxylic acid diesters such as maleic acid diethyl, fumaric acid dibutyl, or the like; aromatic compounds containing a vinyl group such as styrene, α-methylstyrene, chlorostyrene, chloromethylstyrene, vinyltoluene, hydroxystyrene, α-methylhydroxystyrene, α-ethylhydroxystyrene, or the like; aliphatic compounds containing a vinyl group such as acetic acid vinyl or the like; conjugated diolefins such as butadiene, isoprene, or the like; a polymerizable compound containing a nitrile group such as acrylonitrile, methacrylonitrile, or the like; a polymerizable compound containing chloride such as vinyl chloride, vinylidene chloride, or the like; a polymerizable compound containing an amide bond such as acrylamide, methacrylic amide, or the like.

In an implementation, the photosensitive polymer may be a copolymer including a first repeating unit represented by Chemical Formula 2 and a second repeating unit represented by Chemical Formula 1. The first repeating unit and the second repeating unit may be copolymerized randomly or in the form of blocks. In an implementation, the first repeating unit and the second repeating unit may be randomly copolymerized.

In an implementation, the first repeating unit may include a protecting group and R^{1b} of the second repeating unit may be a hydroxy group or a carboxyl group. In an implementation, the second repeating unit may include one of the following moieties (e.g., including a hydroxyl group or a carboxyl group).

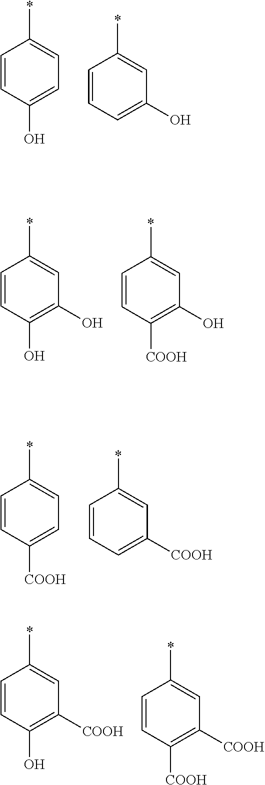

In the formulae above, “*” denotes a bonding position.

In an implementation, the second repeating unit may include a protecting group and R^{2b} of the first repeating unit may be a hydrogen atom.

The photosensitive polymer may have a weight average molecular weight (Mw) of, e.g., about 10,000 to about 600,000. In an implementation, the photosensitive polymer may have Mw of, e.g., about 20,000 to about 400,000, or about 30,000 to about 300,000. In an implementation, the Mw may be a value measured by gel permeation chromatography (GPC) with polystyrene as a standard.

The photosensitive polymer may have a polydispersity index PI of about 1 to about 3. The photosensitive polymer may be included in the photoresist composition in an amount of about 5 wt % to about 60 wt %, based on a total weight of the photoresist composition.

Photoacid Generator (PAG)

In an implementation, the photoresist composition may further include a PAG that generates acid by or in response to exposure (e.g., to light).

The PAG may include a material having a different chemical structural formula from a chemical structural formula of the photosensitive compound. In an implementation, the PAG may generate acid when exposed to, e.g., a KrF excimer laser (248 nm wavelength), an ArF excimer laser (193 nm wavelength), an F₂ excimer laser (157 nm wavelength), or an EUV laser (13.5 nm wavelength). The PAG may include a material that generates relatively strong acid having an acid dissociation constant (pKa) of about −20 or more and less than about 1 by exposure. In an implementation, the PAG may include, e.g., a triarylsulfonium salt, a diaryliodonium salt, a sulfonate, or a mixture thereof. In an implementation, the PAG may include, e.g., triphenylsulfonium triflate, triphenylsulfonium antimonate, triphenylsulfonium difluoroalkyl sulfonate, diphenyliodonium triflate, diphenyliodonium antimonate, methoxydiphenyliodonium triflate, di-t-butyldiphenyliodonium triflate, 2,6-dinitrobenzyl sulfonates, pyrogallol tris(alkylsulfonates), N-hydroxysuccinimide triflate, norbornene-dicarboximide-triflate, triphenylsulfonium nonaflate, diphenyliodonium nonaflate, methoxydiphenyliodonium nonaflate, di-t-butyl diphenyliodonium nonaflate, N-hydroxysuccinimide nonaflate, norbornene-dicarboximide-nonaflate, triphenylsulfonium perfluorobutanesulfonate, triphenylsulfonium perfluorooctanesulfonate (PFOS), diphenyliodonium PFOS, methoxydiphenyliodonium PFOS, di-t-butyldiphenyliodonium triflate, N-hydroxysuccinimide PFOS, norbornene-dicarboximide PFOS, or a mixture thereof.

In the photoresist composition according to an embodiment, the PAG may be included in an amount of about 0.1 weight % to about 50 weight %, based on the total weight of the photosensitive polymer. In an implementation, the PAG may be included in an amount of, e.g., about 1 weight % to about 48 weight %, about 3 weight % to about 46 weight %, about 5 weight % to about 44 weight %, about 7 weight % to about 42 weight %, about 10 weight % to about 40 weight %, about 15 weight % to about 38 weight %, or an amount between the above values, based on the total weight of the photosensitive polymer.

Metal Precursor

The metal precursor may have a structure in which an organic ligand forms a coordination bond with a metal atom. In an implementation, the metal precursor may have a structure of Chemical Formula 4.

MₙLₘ Chemical Formula 4

In Chemical Formula 4, M may be, e.g., a metal element having an atomic absorption cross section of 5×10⁶ cm²/mole or more with respect to the irradiation of light of a 13.5 nm wavelength. L may be or may include, e.g., a halogen, a straight-chain or branched-chain alkyl group having a carbon number of 2 to 12, an alkenyl group having a carbon number of 2 to 12, an alkynyl group having a carbon number of 2 to 12, an alkoxy group having a carbon number of 1 to 12, a cycloalkyl group having a carbon number of 3 to 15, an aryl group having a carbon number of 6 to 20, an aryloxy group having a carbon number of 6 to 20, an allyl group having a carbon number of 3 to 15, a carboxylate group having a carbon number of 2 to 20, or a (meth)acrylate group having a carbon number of 2 to 20. n may be, e.g., an integer of 1 to 12. m may be, e.g., an integer of 2 to 72. In an implementation, m=2n to 6n.

The metal precursor may emit secondary electrons by or in response to the irradiation of a KrF excimer laser (248 nm wavelength), an ArF excimer laser (193 nm wavelength), an F₂ excimer laser (157 nm wavelength), or an EUV light (13.5 nm wavelength), e.g., the irradiation of EUV light, thereby generating metal ions.

In an implementation, the metal element M may have an atomic absorption cross section of 5×10⁶ cm²/mole or more with respect to the irradiation of light of a 13.5 nm wavelength. In an implementation, the metal element M may include, e.g., polonium (Po), tellurium (Te), titanium (Ti), lead (Pb), gold (Au), silver (Ag), cesium (Cs), bismuth (Bi), tin (Sn), zinc (Zn), antimony (Sb), indium (In), cadmium (Cd), or astatine (At).

In an implementation, L may have a structure represented by the following formula: —X—R, e.g., as an organic ligand. In the formula, R may be, e.g., an alkyl group having a carbon number of 1 to 11, and —X— may be, e.g., —O— or —COO—. In an implementation, L may be, e.g., methoxy, ethoxy, n-propoxy, isopropoxy, n-butoxy, isobutoxy, tert-butoxy, sec-butoxy, n-pentyloxy, neopentyloxy, isopentyloxy, n-hexyloxy, 1,2-dimethylbutoxy, 3,3-dimethylbutoxy, 2-ethylbutoxy, n-octyloxy, n-nonyloxy, n-decyloxy, acetate, propionate, butyrate, pentanoate, valerate, hexanoate, heptylate, caprylate, pelargonate, decanoate, undecanoate, laurate, stearate, pivalate, or benzoate.

In an implementation, the metal precursor may be, e.g., tin (II) ethoxide, tin (IV) n-butoxide, tin (IV) tert-butoxide, tin (IV) acetate, tin (II) 2-ethylhexanoate, dibutyl tin chloride, lead (II) acetate hydrate, zinc acetate hydrate, or titanium (IV) isopropoxide.

In the photoresist composition according to embodiments, the metal precursor may be included in an amount of, e.g., about 2 weight % to about 10 weight %, about 3 weight % to about 7.5 weight %, or about 4 weight % to about 6 weight %, based on the total weight of the photosensitive polymer. If the amount of the metal precursor were to be too small, an effect according to the addition of the metal precursor may be insufficient. If the amount of the metal precursor were to be too large, the resolution of a pattern may be excessively lowered.

Solvent

A solvent included in the photoresist composition may include an organic solvent. The organic solvent may include, e.g., ether, alcohol, glycolether, aromatic hydrocarbon compound, ketone, or ester. In an implementation, the organic solvent may include, e.g., ethylene glycol monomethyl ether, ethylene glycol monoethyl ether, methyl cellosolve acetate, ethyl cellosolve acetate, diethylene glycol methyl ether, diethylene glycol ethyl ether, propylene glycol, propylene glycol methyl ether (PGME), propylene glycol methyl ether acetate (PGMEA), propylene glycol ethyl ether, propylene glycol ethyl ether acetate, propylene glycol propyl ether acetate, propylene glycol butyl ether, propylene glycol butyl ether acetate, ethanol, propanol, isopropyl alcohol, isobutyl alcohol, 4-methyl-2-pentanol (methyl isobutyl carbinol: MIBC), hexanol, 1-methoxy-2-propanol, 1-ethoxy-2-propanol, ethylene glycol, propylene glycol, heptanone, propylene carbonate, butylene carbonate, toluene, xylene, methyl ethyl ketone, cyclopentanone, cyclohexanone, 2-hydroxypropionate ethyl, 2-hydroxy-2-methyl propionate ethyl, ethoxy acetic acid ethyl, hydroxyl acetic acid ethyl, 2-hydroxy-3-methyl methyl butanoate, 3-methoxy propionate methyl, 3-methoxy propionate ethyl, 3-ethoxy propionate ethyl, 3-ethoxy propionate methyl, methyl pyruvate, ethyl pyruvate, acetic acid ethyl, acetic acidbutyl, ethyl lactate, butyl lactate, gamma-butyrolactone, methyl-2-hydroxyiso butyrate, methoxybenzene, n-butyl acetate, 1-methoxy-2-propyl acetate, methoxyethoxy propionate, ethoxyethoxy propionate, or a combination thereof.

In the photoresist composition according to embodiments, the solvent may be included as a remaining or balance amount except the content of the other major constituents including, e.g., the metal precursor, a basic quencher, and the photoacid generator. In an implementation, the solvent may be included in an amount of, e.g., about 0.1 weight % to about 99.7 weight %, based on the total weight of the photoresist composition.

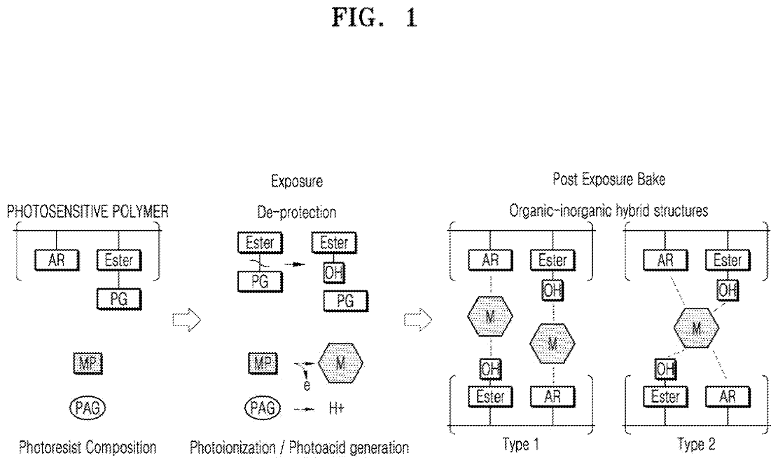

FIG. 1 is a conceptual view schematically showing a mechanism of a photoresist composition according to an embodiment being cured by exposure and post exposure bake (PEB).

Referring to FIG. 1, the photoresist composition may include a photosensitive polymer, a PAG, and a metal precursor MP.

The photosensitive polymer may include a first repeating unit including an ester group and a second repeating unit including an aryl group AR. In an implementation, as illustrated in FIG. 1, the first repeating unit and the second repeating unit may form one repeating unit. The first repeating unit and the second repeating unit may form a random copolymer or a block copolymer. In an implementation, as illustrated in FIG. 1, the first repeating unit may include a protecting group PG, or the second repeating unit may include the protecting group PG.

Thereafter, when light, e.g., light of a 13.5 nm wavelength, is irradiated to the photoresist composition, the PAG may emit secondary electrons and may be converted to acid. Furthermore, the metal precursor MP may also emit secondary electrons and may be converted to metal ions M by being separated from a ligand. In an implementation, as some protecting groups are dissociated by the presence of the acid, the photosensitive polymer may be deprotected.

When a post exposure bake is performed on the exposed photoresist composition, the deprotection of the photosensitive polymer may be further accelerated. The ester group of the first repeating unit and the aryl group of the second repeating unit may form coordination bonds with the metal ions M. In FIG. 1, Type 1 illustrates an example in which the ester group and the aryl group are coordinated one by one with respect to one of the metal ions M, and Type 2 illustrates an example in which the ester group and the aryl group are coordinated two by two with respect to one of the metal ions M. The number of ester groups and aryl groups coordinated with one of the metal ions M may be two or more, and a cross-link structure may be obtained with respect to the metal ions M. The cross-link structure may help improve a resolution of the exposed photoresist composition.

Quencher

The photoresist composition according to embodiments may further include a basic quencher.

When the acid generated from the PAG included in the photoresist composition according to embodiments diffuses into a non-exposed region of a photoresist film, the basic quencher may trap the acid in the non-exposed region. The photoresist composition according to embodiments may include the basic quencher, and acid generated in the exposed region of the photoresist film after the exposure of the photoresist film obtained from the photoresist composition may be prevented from diffusing into the non-exposed region of the photoresist film.

In an implementation, the basic quencher may include, e.g., primary aliphatic amine, secondary aliphatic amine, tertiary aliphatic amine, aromatic amine, heterocyclic ring containing amine, a nitrogen containing compound having a carboxyl group, a nitrogen containing compound having a sulfonyl group, a nitrogen containing compound having a hydroxyl group, a nitrogen containing compound having a hydroxyphenyl group, an alcoholic nitrogen containing compound, amides, imides, carbamates, or ammonium salts. In an implementation, the basic quencher may include, e.g., triethanol amine, triethyl amine, tributyl amine, tripropyl amine, hexamethyl disilazan, aniline, N-methylaniline, N-ethyl aniline, N-propylaniline, N,N-dimethylaniline, N,N-bis(hydroxyethyl)aniline, 2-methylaniline, 3-methylaniline, 4-methylaniline, ethylaniline, propylaniline, dimethylaniline, 2,6-diisopropylaniline, trimethylaniline, 2-nitroaniline, 3-nitroaniline, 4-nitroaniline, 2,4-dinitroaniline, 2,6-dinitroaniline, 3,5-dinitroaniline, N,N-dimethyl toluidine, or a combination thereof.

In an implementation, the basic quencher may include a photodegradable base. The photodegradable base may include a compound that generates acid by exposure and neutralizes the acid before the exposure. The photodegradable base, when degraded by exposure, may lose a function to trap the acid. Accordingly, when a partial region of a photoresist film formed from a chemical amplification type photoresist composition including a basic quencher including the photodegradable base is exposed, the photodegradable base may lose alkalinity in the exposed region of the photoresist film, and as the photodegradable base traps acid in the non-exposed region of the photoresist film, diffusion of the acid generated from the exposed region of the photoresist film into the non-exposed region of the photoresist film may be prevented.

The photodegradable base may include carboxylate or sulfonate salts of photodegradable cations. In an implementation, the photodegradable cations may form a complex with anions of carboxylic acid having a carbon number of 1 to 20. The carboxylic acid may include, e.g., formic acid, acetic acid, propionate, tartaric acid, succinic acid, cyclohexylcarboxylic acid, benzoic acid, or salicylic acid.

In the photoresist composition according to embodiments, the basic quencher may be included in an amount of, e.g., about 0.01 weight % to about 5.0 weight %, based on the total weight of the photoresist composition.

Other Ingredients

In an implementation, the photoresist composition may further include, e.g., a surfactant, a dispersant, a moisture absorbent, or a coupling agent.

The surfactant may help improve the coating uniformity of the photoresist composition and improve wettability. In an implementation, the surfactant may include, e.g., sulfuric acid ester salts, sulfonic acid salts, phosphoric acid ester, soap, amine salts, quaternary ammonium salts, polyethylene glycol, alkyl phenol ethylene oxide adducts, polyhydric alcohol, nitrogen containing vinyl polymers, or a combination thereof. In an implementation, the surfactant may include, e.g., alkyl benzene sulfonic acid salts, alkyl pyridinium salts, polyethylene glycol, or quaternary ammonium salts. When the photoresist composition includes a surfactant, the surfactant may be included in an amount of about 0.001 weight % to about 3 weight %, based on the total weight of the photoresist composition.

The dispersant may help ensure that each component constituting the photoresist composition is uniformly dispersed within the photoresist composition. In an implementation, the dispersant may include, e.g., epoxy resin, polyvinyl alcohol, polyvinyl butyral, polyvinyl pyrrolidone, glucose, sodium dodecyl sulfate, sodium citrate, oleic acid, linoleic acid, or a combination thereof. When the photoresist composition includes a dispersant, the dispersant may be included in an amount of about 0.001 weight % to about 5 weight %, based on the total weight of the photoresist composition.

The moisture absorbent may help prevent an adverse effect of moisture in the photoresist composition. In an implementation, the moisture absorbent may help prevent a metal included in the photoresist composition from being oxidized by moisture. In an implementation, the moisture absorbent may include, e.g., polyoxymethylene nonylphenolether, polyethylene glycol, polypropylene glycol, polyacrylamide, or a combination thereof. When the photoresist composition includes a moisture absorbent, the moisture absorbent may be included in an amount of about 0.001 weight % to about 10 weight %, based on the total weight of the photoresist composition.

When the photoresist composition is coated on a lower film, the coupling agent may help increase adhesion to the lower film. In an implementation, the coupling agent may include a silane coupling agent. In an implementation, the silane coupling agent may include, e.g., vinyltrimethoxysilane, vinyltriethoxysilane, vinyltrichlorosilane, vinyltris(β-methoxyethoxy)silane, 3-methacrylicoxypropyltrimethoxysilane, 3-acryloxypropyltrimethoxysilane, p-styryl trimethoxysilane, 3-methacrylicoxypropylmethyldimethoxysilane, 3-methacrylicoxypropylmethyldiethoxysilane, or trimethoxy[3-(phenylamino)propyl]silane. When the photoresist composition includes a coupling agent, the coupling agent may be included in an amount of about 0.001 weight % to about 5 weight %, based on the total weight of the photoresist composition.

In the photoresist composition according to embodiments, when the solvent includes an organic solvent only, the photoresist composition may further include water. In this case, a water content in the photoresist composition may be about 0.001 weight % to about 0.1 weight %.

Fabrication of Integrated Circuit Device

Next, a method of fabricating an integrated circuit device by using the photoresist composition according to an embodiment is described in detail.

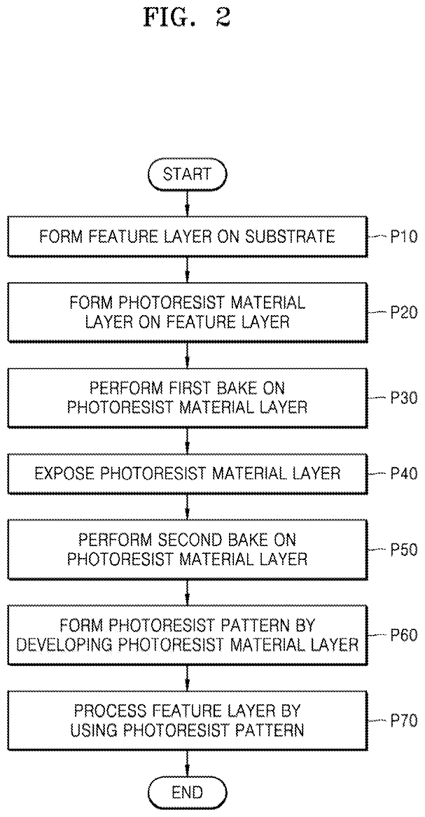

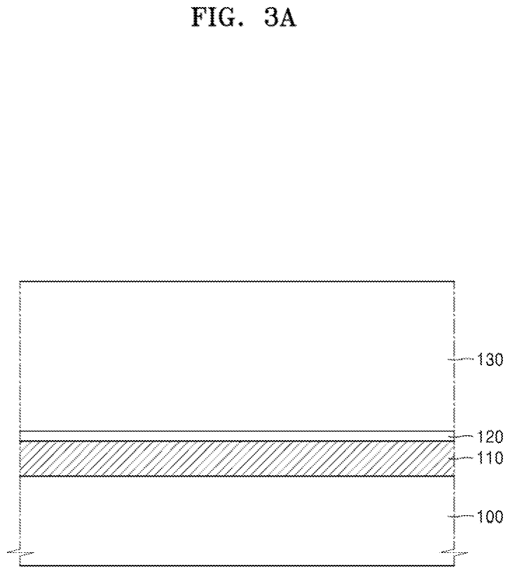

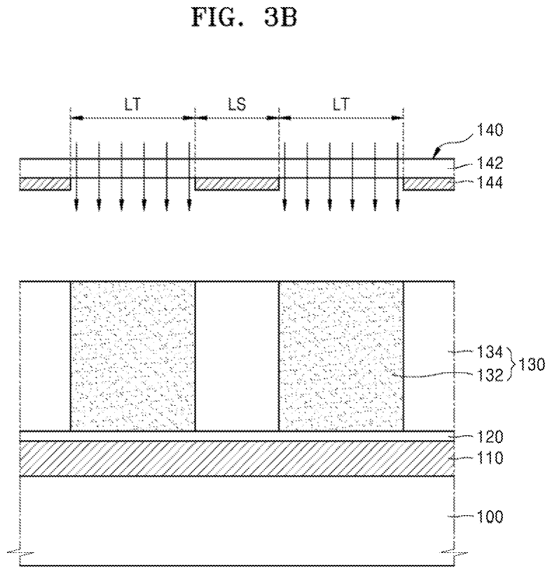

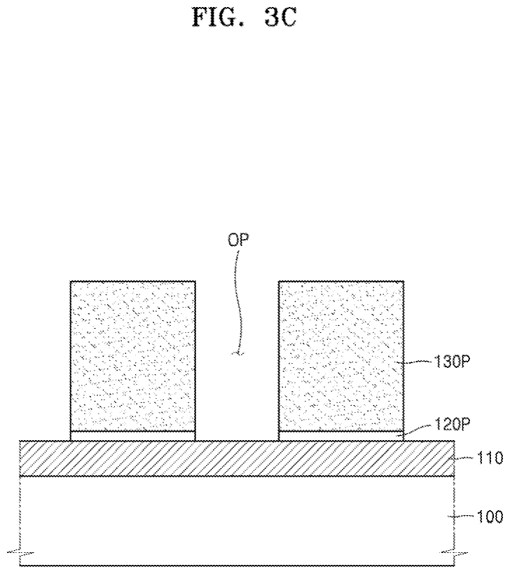

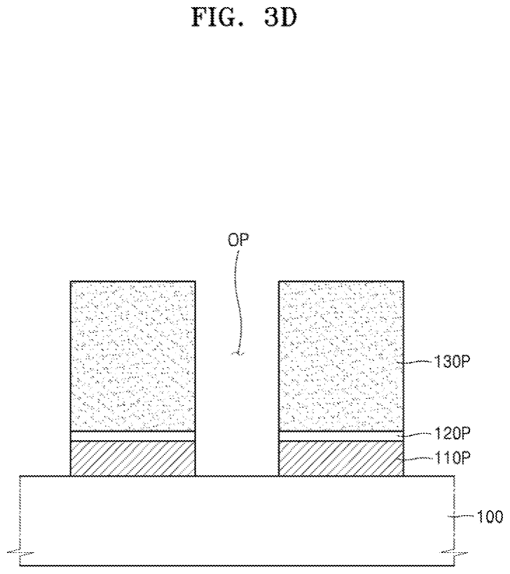

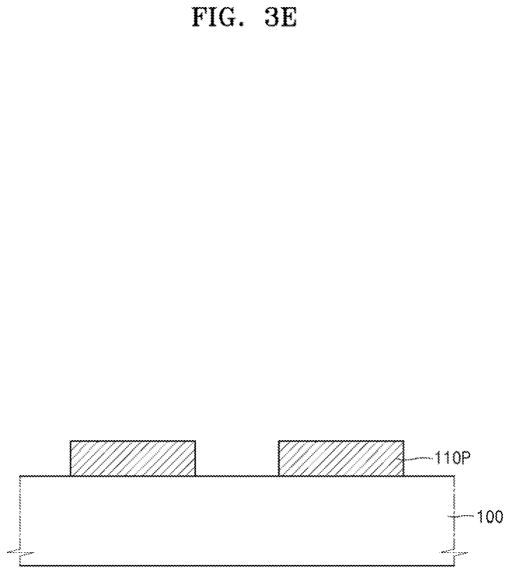

FIG. 2 is a flowchart of a method of fabricating an integrated circuit device, according to embodiments. FIGS. 3A to 3E are cross-sectional views of stages in a method of fabricating an integrated circuit device, according to embodiments.

Referring to FIGS. 2 and 3A, in a process P10, a feature layer 110 may be formed on a substrate 100, and in a process P20, a photoresist film 130 may be formed on the feature layer 110 by using the photoresist composition according to an embodiment.

The photoresist film 130 may include a metal precursor and a solvent that are constituent elements of the photoresist composition. The detailed configuration of the photoresist composition is as described above.

The substrate 100 may include a semiconductor substrate. The feature layer 110 may be an insulating film, a conductive film, or a semiconductor film. In an implementation, the feature layer 110 may include, e.g., a metal, an alloy, a metal carbide, a metal nitride, a metal oxynitride, a metal oxycarbide, a semiconductor, a polysilicon, an oxide, a nitride, an oxynitride, or a combination thereof.

In an implementation, as illustrated in FIG. 3A, a lower film 120 may be formed on the feature layer 110 before the photoresist film 130 is formed on the feature layer 110. In this case, the photoresist film 130 may be formed on the lower film 120. The lower film 120 may help prevent an adverse effect that the photoresist film 130 could receive from the feature layer 110 thereunder. In an implementation, the lower film 120 may include, e.g., an organic or inorganic anti-reflective coating (ARC) material for a KrF excimer laser, an ArF excimer laser, an EUV laser, or other light sources. In an implementation, the lower film 120 may include a bottom anti-reflective coating (BARC) film or a developable bottom anti-reflective coating (DBARC) film. In an implementation, the lower film 120 may include an organic component having a light absorption structure. The light absorption structure may be, e.g., a hydrocarbon compound having a structure of one or more benzene rings or fused benzene rings. In an implementation, the lower film 120 may have a thickness of, e.g., about 1 nm to about 100 nm. In an implementation, the lower film 120 may be omitted.

To form the photoresist film 130, the photoresist composition according to an embodiment may be coated on the lower film 120. The coating may be performed by, e.g., spin coating, spray coating, dip coating, or the like. The thickness of the photoresist film 130 may be several tens to hundreds times the thickness of the lower film 120. In an implementation, the photoresist film 130 may have a thickness of about 10 nm to about 1 μm.

In process P30, a first bake may be performed on the photoresist film 130. The first bake may be referred to as a postapply bake (PAB).

The first bake may be performed, e.g., at a temperature of about 80° C. to about 140° C. or about 90° C. to about 120° C. for about 10 seconds to about 100 seconds. If the temperature of the first bake were to be too low, the removal of solvent could be insufficient. If the temperature of the first bake were to be too high, the resolution of photoresist pattern could be deteriorated.

Referring to FIGS. 2 and 3B, in a process P40, by exposing a first area 132 that is part of the photoresist film 130, in the first area 132, a metal precursor emitting secondary electrons may be separated from a ligand and converted to metal ions.

In an implementation, to expose the first area 132 of the photoresist film 130, a photomask 140 having a plurality of light shielding areas LS and a plurality of light transmitting areas LT may be aligned with a certain position on the photoresist film 130, and the first area 132 of the photoresist film 130 may be exposed through the light transmitting areas LT of the photomask 140. To expose the first area 132 of the photoresist film 130 a KrF excimer laser (248 nm wavelength), an ArF excimer laser (193 nm wavelength), an F₂ excimer laser (157 nm wavelength), or an EUV laser (13.5 nm wavelength) may be used. In an implementation, rather than a transmissive photomask, a reflective photomask may be used according to the type of a light source. While the transmissive photomask is mainly described in the following description, exposure may be performed by the same configuration on the reflective photomask.

The photomask 140 may include a transparent substrate 142 and a plurality of light shielding patterns 144 on the transparent substrate 142 in a plurality of light shielding areas LS. In an implementation, the transparent substrate 142 may include, e.g., quartz. In an implementation, the light shielding patterns 144 may include, e.g., chromium (Cr). The light transmitting areas LT may be defined by the light shielding patterns 144. In an implementation, to expose the first area 132 of the photoresist film 130, a reflective photomask for EUV exposure may be used instead of the photomask 140.

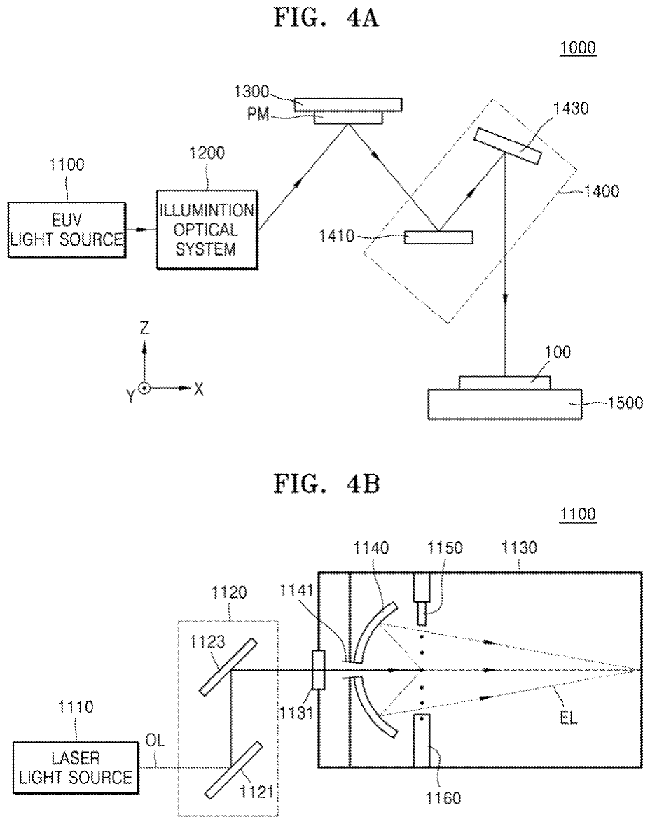

FIGS. 4A and 4B are schematic views for describing EUV exposure performed on the photoresist film 130 on the feature layer 110.

Referring to FIGS. 4A and 4B together, an EUV exposure device 1000 may include an EUV light source 1100, an illumination optical system 1200, a photomask support 1300, a projection optical system 1400, and a substrate stage 1500.

The EUV light source 1100 may generate and output EUV light EL having a high energy density. In an implementation, the EUV light EL radiated from the EUV light source 1100 may have a wavelength of about 4 nm to 124 nm. In an implementation, the EUV light EL may have a wavelength of about 4 nm to 20 nm, e.g., the EUV light EL may have a wavelength of 13.5 nm.

The EUV light source 1100 may be a plasma light source or a synchrotron radiation light source. The plasma light source refers to a light source using a method of generating plasma and using light emitted by the plasma, and may include a laser produced plasma light source, a discharge produced plasma light source, or the like.

The EUV light source 1100 may include a laser light source 1110, a relay optical system 1120, a vacuum chamber 1130, a collector mirror 1140, a droplet generator 1150, and a droplet catcher 1160.

The laser light source 1110 may be configured to output laser OL. In an implementation, the laser light source 1110 may output carbon dioxide laser. The laser OL output from the laser light source 1110 may be incident on a window 1131 of the vacuum chamber 1130 through a plurality of reflection mirrors 1121 and 1123 included in the relay optical system 1120, and may be introduced into the vacuum chamber 1130.

An aperture 1141 through which the laser OL may pass may be formed at the center portion of the collector mirror 1140, and the laser OL may be introduced into the vacuum chamber 1130 through the aperture 1141 of the collector mirror 1140.

The droplet generator 1150 may generate a droplet for generating the EUV light EL in interaction with the laser OL, and may provide the droplet to the inside of the vacuum chamber 1130. The droplet may include, e.g., tin (Sn), lithium (Li), or xenon (Xe). In an implementation, the droplet may include, e.g., Sn, a tin compound, for example, SnBr₄, SnBr₂, or SnH, or a tin alloy, for example, Sn—Ga, Sn—In, or Sn—In—Ga.

The droplet catcher 1160 may be located under the droplet generator 1150, and may be configured to collect droplets that do not react with the laser OL. The droplets provided by the droplet generator 1150 may react with the laser OL introduced into the vacuum chamber 1130 to generate the EUV light EL. The collector mirror 1140 that collects and reflects the EUV light EL may emit the EUV light EL to the illumination optical system 1200 that is arranged outside the vacuum chamber 1130.

The illumination optical system 1200 may include the reflection mirrors 1121 and 1123, and may transfer the EUV light EL emitted from the EUV light source 1100 to an EUV photomask PM. In an implementation, the EUV light EL emitted from the EUV light source 1100 may be reflected by the reflection mirrors 1121 and 1123 in the illumination optical system 1200, to be incident on the EUV photomask PM arranged on the photomask support 1300.

The EUV photomask PM may be a reflective mask having a reflective area and non-reflective (or intermediate reflective) area. The EUV photomask PM may include a reflective multilayer film formed on a mask substrate that is formed of a material having a low thermal expansion coefficient, e.g., silicon (Si), and an absorption pattern formed on the reflective multilayer film. The reflective multilayer film may correspond to the reflective area, and the absorption pattern may correspond to the non-reflective (or intermediate reflective) area.

The EUV photomask PM may reflect the EUV light EL input through the illumination optical system 1200 to be incident on the projection optical system 1400. In an implementation, the EUV photomask PM may structure the light input from the illumination optical system 1200 as projection light, and may input the light to the projection optical system 1400, based on a pattern form formed by the reflective multilayer film and the absorption pattern on the mask substrate. The projection light may be structured by the EUV photomask PM through at least second order of diffraction. The projection light may be incident on the projection optical system 1400 while keeping information about the pattern form of the EUV photomask PM, and may pass through the projection optical system 1400, thereby forming an image corresponding to the pattern form of the EUV photomask PM on a substrate 100.

The projection optical system 1400 may include a plurality of reflection mirrors 1410 and 1430. In an implementation, as illustrated in the drawings, there may be two reflection mirrors 1410 and 1430 in the projection optical system 1400, or the projection optical system 1400 may more reflection mirrors. In an implementation, the projection optical system 1400 may generally four to eight reflection mirrors.

The substrate 100 may be arranged on the substrate stage 1500. The substrate stage 1500 may move on an X-Y plane in a first direction (X direction) and a second direction (Y direction), and may move in a third direction (Z direction) perpendicular to the X-Y plane. Due to the movement of the substrate stage 1500, the substrate 100 may also move likewise in the first direction (X direction), the second direction (Y direction), and/or the third direction (Z direction).

When the EUV light is in use, a light quantity needed for exposure in a critical dimension uniformity (CDU) of 27 nm may be about 25 mJ/cm² to about 30 mJ/cm². In an implementation, when the other conditions are the same, an inverse relationship may be established between the CDU and the exposure light quantity required for normal patterning, based on a 27 nm CDU, the photoresist composition according to embodiments may need light quantity of about 25 mJ/cm² to about 30 mJ/cm². The light quantity may be a significantly low light quantity, compared to other photoresist compositions that do not use a metal precursor, which means that a time for exposure may be shorter and furthermore productivity may be improved.

After the first area 132 of the photoresist film 130 is exposed according to the process P40, in a process P50, the photoresist film 130 may be secondarily baked. The second bake may be referred to as post exposure bake (PEB). The second bake may be performed at, e.g., a temperature of about 50° C. to about 400° C. for about 10 seconds to about 100 seconds. In an implementation, as the photoresist film 130 is secondarily baked, a degree of cross-linking between photosensitive polymer molecules in the first area 132 may be further increased. Accordingly, a solubility difference between the first area 132 that is exposed and a second area 134 that is not exposed, of the photoresist film 130, to a developer, may be further increased and thus pattern collapse may be prevented.

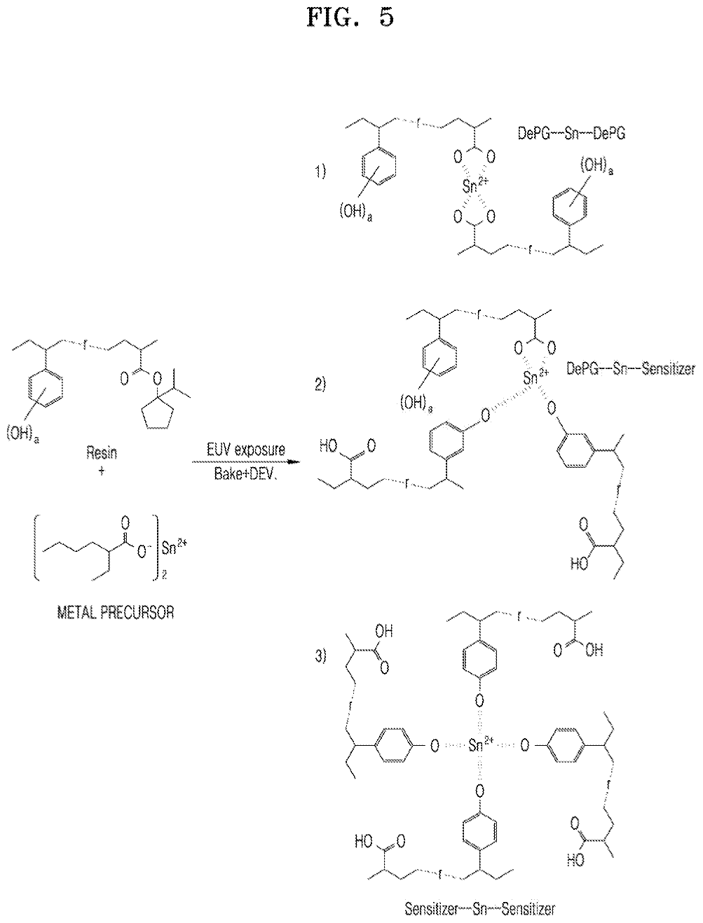

In an implementation, as a phenomenon that, due to the second bake, the photosensitive polymers form coordination bonds with the metal ions to be cross-linked is widespread, macromolecules that are difficult to be removed by the developer may be formed. Without being bound to a specific theory, the mechanism that the photosensitive polymers form coordination bonds with the metal ions to be cross-linked may be as described above with reference to FIG. 1, and a specific example is described below in detail with reference to FIG. 5.

FIG. 5 is a schematic view of an exemplary process for cross-linking a photosensitive polymer by using a metal precursor.

Referring to FIG. 5, poly(hydroxystyrene-r-isopropyl cyclopentyl methacrylate) may be provided as the photosensitive polymer, and tin (II) 2-ethylhexanoate may be provided as the metal precursor. The photosensitive polymer may have a first repeating unit having isopropyl cyclopentyl methacrylate and a second repeating unit having hydroxystyrene. The hydroxystyrene may include one, two, or three or more hydroxy groups. In FIG. 5, the number of hydroxy groups is an integer of 1 to 5.

Sn²⁺ ions may be generated as ligands are removed from the metal precursor through EUV exposure, and an isopropyl cyclopentyl group (that is a protecting group of the photosensitive polymer) may be separated from an ester group by acid. The photosensitive polymer molecules may form coordination bonds with Sn²⁺ ions in various ways may form/be formed.

As illustrated in part 1) of FIG. 5, oxygen atoms of a deprotected ester group may form coordination bonds with Sn²⁺ ions along with oxygen atoms of a deprotected ester group of other molecules or segments. As illustrated in part 2) of FIG. 5, oxide atoms of a deprotected ester group may form coordination bonds with Sn²⁺ ions along with oxygen atoms of hydroxystyrene of other molecules or segments. As illustrated in part 3) of FIG. 5, oxygen atoms of hydroxystyrene may form coordination bonds with Sn²⁺ ions along with oxygen atoms of hydroxystyrene of other molecules or segments.

As such, the metal precursors of the first area 132 that is exposed may be converted to metal ions, and the photosensitive polymers may be cross-linked to each other to form giant molecules. The metal precursors of the second area 134 that is not exposed may maintain a (e.g., bound) state thereof, and thus the photosensitive polymers may not be cross-linked to each other. Accordingly, a solubility difference may be generated between the cross-linked giant molecule and the photosensitive polymer molecules that are not cross-linked to each other.

Referring to FIGS. 2 and 3C, in a process P60, the second area 134 of the photoresist film 130 may be removed by developing the photoresist film 130 by using a developer. As a result, a photoresist pattern 130P including the first area 132 (e.g., exposed area) of the photoresist film 130 may be formed.

The photoresist pattern 130P may include a plurality of openings OP. After the photoresist pattern 130P is formed, a lower pattern 120P may be formed by removing a portion of the lower film 120 that is exposed through the openings OP.

In an implementation, the development of the photoresist film 130 may be performed in a negative-tone development (NTD) process. In this state, n-butyl acetate or 2-heptanone may be used as a developer.

As described with reference to FIG. 3B, as the solubility difference in developer between the first area 132 (that is exposed) and the second area 134 (that is not exposed), in the photoresist film 130, increases, in the process of FIG. 3C, as the second area 134 is removed by developing the photoresist film 130, the first area 132 may be left without being removed. Accordingly, after the development of the photoresist film 130, a residual defect (e.g., footing development or the like) may not be generated, and a vertical side wall profile may be obtained from the photoresist pattern 130P. As such, the profile of the photoresist pattern 130P may be improved, and when the feature layer 110 is processed by using the photoresist pattern 130P, the critical dimensions of a machining area intended by the feature layer 110 may be precisely controlled.

Referring to FIGS. 2 and 3D, in a process P70, the feature layer 110 may be processed from a resultant of FIG. 3C by using the photoresist pattern 130P.

In order to process the feature layer 110, various processes such as a process of etching the feature layer 110 that is exposed through the openings OP of the photoresist pattern 130P, a process of injecting impurities ions into the feature layer 110, a process of forming an additional film on the feature layer 110 through the openings OP, a process of deforming a portion of the feature layer 110 through the openings OP, or the like. FIG. 3D illustrates a case in which a feature pattern 110P is formed by etching the feature layer 110 that is exposed through the openings OP, as an exemplary process of processing the feature layer 110.

In an implementation, in the process described with reference to FIG. 3A, a formation process of the feature layer 110 may be omitted, and the substrate 100 may be processed by using the photoresist pattern 130P, instead of the process P70 of FIG. 2 and the process described with reference to FIG. 3D. In an implementation, various processes such as a process of etching a portion of the substrate 100 by using the photoresist pattern 130P, a process of injecting impurities ions into a partial area of the substrate 100, a process of forming an additional film on the substrate 100 through the openings OP, a process of deforming a portion of the substrate 100 through the openings OP, or the like may be performed.

Referring to FIG. 3E, the photoresist pattern 130P and the lower pattern 120P remaining on the feature pattern 110P may be removed from the resultant of FIG. 3D. To remove the photoresist pattern 130P and the lower pattern 120P, ashing and strip processes may be used.

In the method of fabricating an integrated circuit device according to the embodiment described with reference to FIG. 2 and FIGS. 3A to 3E, as not only the secondary electrons are generated from the PAG by the exposure, but also the secondary electrons are generated from the metal precursor, deprotection of a protecting group may be possible more quickly, and accordingly, the light quantity required for the same level of exposure may be reduced, thereby obtaining effects of reducing a time for exposure and improving productivity. Also, as the moieties of the photosensitive polymer form coordination bonds with metal ions from the metal precursor to form a cross-link structure, the contrast, e.g., resolution, of a pattern may be greatly improved. Furthermore, as the metal ions remain in the photoresist pattern, when anisotropic etching is performed, the etching resistance of a photoresist pattern may be improved.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES 1 to 3

Photoresist compositions including poly(3,4-dihydroxystyrene-r-isopropyl cyclopentyl methacrylate) as a photosensitive polymer, triphenylsulfonium difluoroalkylsulfonate as a PAG, and tin (II) 2-ethylhexanoate as a metal precursor were prepared by changing the content of the metal precursor, as seen in Table 1, below.

### EXAMPLES 4 to 6

Photoresist compositions including poly(monohydroxystyrene-r-isopropyl cyclopentyl methacrylate) as a photosensitive polymer, triphenylsulfonium difluoroalkylsulfonate as a PAG, and tin (II) 2-ethylhexanoate as a metal precursor were prepared by changing the content of the metal precursor, as seen in Table 1, below.

### COMPARATIVE EXAMPLE 1

A photoresist composition was prepared in the same method as Example 1, except that the metal precursor was not added.

### COMPARATIVE EXAMPLE 2

A photoresist composition is prepared in the same method as Example 1, except the content of the metal precursor was changed, as shown in Table 1, below.

The photoresist compositions according to Examples 1 to 6, Comparative Example 1, and Comparative Example 2 were each coated on a substrate, and then, EUV exposure was performed by using ASML NXE3350 equipment to form a pillar pattern and development was performed by using n-butyl acetate. Then, the resultant was analyzed and a result is summarized as shown in Table 1. PAB and PEB were both performed at 100° C. for 60 seconds.

TABLE 1

| | Content of | | |
|---|---|---|---|
| | Metal Precursor | | |
| | (wt % for | | Amount of |
| | photosensitive | | exposure |
| | polymer) | CDU (nm) | (mJ/cm²) |
| Example 1 | 5 | 4.07 | 86.6 |
| Example 2 | 7.5 | 4.75 | 77.2 |
| Example 3 | 10 | 4.76 | 67.7 |
| Example 4 | 5 | 4.53 | 96.3 |
| Example 5 | 7.5 | 4.65 | 89.4 |
| Example 6 | 10 | 4.29 | 84.9 |
| Comparative | 0 | 3.9 | 103.6 |
| Example 1 | | | |
| Comparative | 15 | — | X |
| Example 2 | | | |

As may be seen in Table 1, when 15 wt % of the metal precursor was included (Comparative Example 2), a photoresist pattern was not formed well. When 5 wt % to 10 wt % of the metal precursor was added (Examples 1 to 6), a photoresist pattern was formed well with a less exposure dose than that when the metal precursor was not added (Comparative Example 1). This means that a time for exposure was proportional, which is directly related to the improvement of productivity.

### COMPARATIVE EXAMPLE 3

The patterning of a photoresist material film was performed in the same method as Example 1, except that the PAB temperature was changed to 150° C.

TABLE 2

| | Content | | | |
|---|---|---|---|---|
| | of Metal | | | Amount of |
| | Precursor | PAB/PEB | | exposure |
| | (wt %) | (° C./° C.) | CDU (nm) | (mJ/cm²) |
| Example 1 | 5 | 100/100 | 3.7 | 27 |
| Comparative | 0 | 100/100 | 3.33 | 35.4 |
| Example 1 | | | | |
| Comparative | 5 | 150/100 | — | X |
| Example 3 | | | | |

As may be seen in Table 2, compared to Comparative Example 1, in Example 1, a photoresist pattern was formed well with a remarkably small exposure dose. In Comparative Example 3, compared to Example 1, a photoresist pattern was not formed well even when a PAB temperature was only changed to 150° C., and, e.g., 5 wt % of the metal precursor was added, or the same amount as in Example 1.

As shown in Table 1 and Table 2, the content of the metal precursor and the temperature at which the PAB is performed affected the formation of the photoresist pattern.

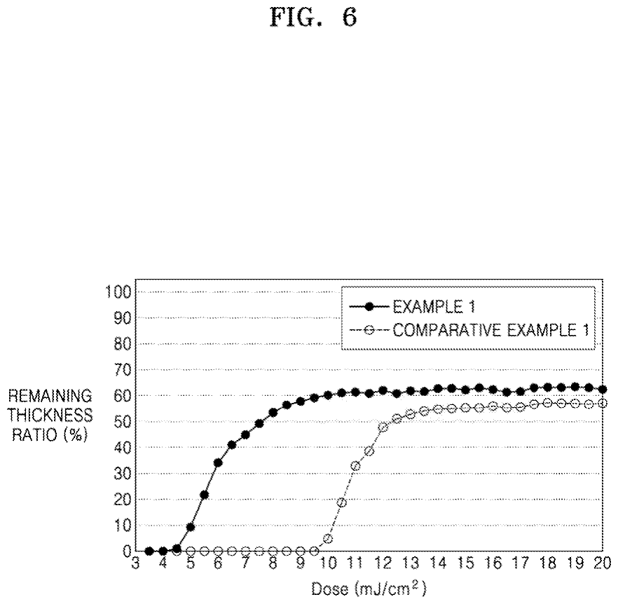

A thickness, e.g., a thickness immediately after development, after patterning by using each of the photoresist compositions of Example 1 and Comparative Example 1 was measured for each exposure dose, and a remaining percentage was calculated compared to the thickness of the initially coated material film, and a result thereof is shown in FIG. 6.

Referring to FIG. 6, the photoresist composition of Example 1 expressed an effect according to exposure, even at a remarkably low exposure dose, compared to the photoresist composition of Comparative Example 1, and thus, a remaining film was formed.

In addition, when a sufficient exposure dose is secured in patterning, a pattern prepared by using the photoresist composition of Comparative Example 1 had a residual thickness ratio of 50% or more and less than 60%. In contrast, a pattern prepared by using the photoresist composition of Example 1 had a residual thickness ratio over 60%. Accordingly, it may be seen that the photoresist composition of Example 1 had better etching resistance than the photoresist composition of Comparative Example 1.

By way of summation and review, light sensitivity may be increased in a photolithography process for the manufacture of integrated circuit devices and a dissolution contrast with respect to a developer between an exposed region and a non-exposed region of a photoresist film may be improved.

One or more embodiments may provide a photoresist composition having excellent resolution, improved productivity, and improved etching resistance. By adding a metal precursor capable of absorbing EUV and emitting secondary electrons, to a photoresist composition, as sensitivity is increased, a resin moiety may form a coordinate bond with metal ions to promote cross-linking and improve resolution.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A photoresist composition, comprising:
a photosensitive polymer having a protecting group;
a photoacid generator (PAG);
a metal precursor, the metal precursor being capable of generating metal ions and secondary electrons in response to irradiating light of a 13.5 nm wavelength thereto; and
a solvent.

2. The photoresist composition as claimed in claim 1, wherein:
the metal precursor has a structure of Chemical Formula (I),
MₙLₘ (I)
in Chemical Formula (I),
M is a metal element having an atomic absorption cross section of 5×10⁶ cm²/mole or more with respect to irradiation of light of a 13.5 nm wavelength,
L is halogen, an alkyl group having a carbon number of 2 to 12, an alkenyl group having a carbon number of 2 to 12, an alkynyl group having a carbon number of 2 to 12, an alkoxy group having a carbon number of 1 to 12, a cycloalkyl group having a carbon number of 3 to 15, an aryl group having a carbon number of 6 to 20, an aryloxy group having a carbon number of 6 to 20, an allyl group having a carbon number of 3 to 15, a carboxylate group having a carbon number of 2 to 20, or a (meth)acrylate group having a carbon number of 2 to 20,
n is an integer of 1 to 12, and
m is an integer of 2 to 72 such that m=2n to 6n.

3. The photoresist composition as claimed in claim 2, wherein M is polonium (Po), tellurium (Te), titanium (Ti), lead (Pb), gold (Au), silver (Ag), cesium (Cs), bismuth (Bi), tin (Sn), zinc (Zn), antimony (Sb), indium (In), cadmium (Cd), or astatine (At).

4. The photoresist composition as claimed in claim 2, wherein:
L has a structure represented by the following formula: —X—R,
R is an alkyl group having a carbon number of 1 to 11, and
—X— is —O— or —COO—.

5. The photoresist composition as claimed in claim 2, wherein:
M includes tin (Sn), and
the metal precursor is included in the photoresist composition in an amount of about 2 wt % to about 10 wt %, based on a total weight of the photosensitive polymer.

6. The photoresist composition as claimed in claim 5, wherein the metal precursor is included in the photoresist composition in an amount of about 3 wt % to about 7.5 wt %, based on the total weight of the photosensitive polymer.

7. The photoresist composition as claimed in claim 2, wherein L is a methoxy, ethoxy, n-propoxy, isopropoxy, n-butoxy, isobutoxy, tert-butoxy, sec-butoxy, n-pentyloxy, neopentyloxy, isopentyloxy, n-hexyloxy, 1,2-dimethylbutoxy, 3,3-dimethylbutoxy, 2-ethylbutoxy, n-octyloxy, n-nonyloxy, n-decyloxy, acetate, propionate, butyrate, pentanoate, valerate, hexanoate, heptylate, caprylate, pelargonate, decanoate, undecanoate, laurate, stearate, pivalate, or benzoate.

8. The photoresist composition as claimed in claim 1, wherein the protecting group is an acid-labile protecting group that is separable from the photosensitive polymer in response to an acid.

9. A photoresist composition, comprising:
a photosensitive polymer having a protecting group;
a photoacid generator (PAG) that generates acid in response to irradiating light of a 13.5 nm wavelength thereto;
a metal precursor having a structure of Chemical Formula (I); and
a solvent,
MₙLₘ (I),
wherein, in Chemical Formula (I),
M is a metal element having an atomic absorption cross section of 5×10⁶ cm²/mole or more with respect to irradiation of light of a 13.5 nm wavelength,
L is halogen, an alkyl group having a carbon number of 1 to 12, an alkenyl group having a carbon number of 2 to 12, an alkynyl group having a carbon number of 2 to 12, an alkoxy group having a carbon number of 1 to 12, a cycloalkyl group having a carbon number of 3 to 15, an aryl group having a carbon number of 6 to 20, an aryloxy group having a carbon number of 6 to 20, an allyl group having a carbon number of 3 to 15, a carboxylate group having a carbon number of 2 to 20, or a (meth)acrylate group having a carbon number of 2 to 20,
n is an integer of 1 to 12, and
m is an integer of 2 to 72 such that m=2n to 6n.

10. The photoresist composition as claimed in claim 9, wherein:
M is tellurium (Te), titanium (Ti), lead (Pb), gold (Au), silver (Ag), cesium (Cs), bismuth (Bi), tin (Sn), zinc (Zn), antimony (Sb), or indium (In), and
n is 1.

11. The photoresist composition as claimed in claim 10, wherein:
M is Sn, and
the metal precursor is included in the photoresist composition in an amount of about 2 wt % to about 10 wt %, based on a total weight of the photosensitive polymer.

12. The photoresist composition as claimed in claim 9, wherein L is a methyl, methoxy, ethyl, ethoxy, isopropyl, isopropoxy, n-butyl, n-butoxy, t-butyl, t-butoxy, acetate, 2-methylpentanoate, 2-ethylpentanoate, 2-methylhexanoate, 2-ethylhexanoate, 3-methylpentanoate, 3-ethylpentanoate, 3-methylhexanoate, 3-ethylhexanoate, 4-methylpentanoate, 4-methylhexanoate, 4-ethylhexanoate, 2,3-dimethylpentanoate, 2,3-dimethylhexanoate, 2,3-diethylpentanoate, 2,3-diethylhexanoate, 2-ethyl-3-methylpentanoate, 2-methyl-3-ethylpentanoate, 2-ethyl-3-methylhexanoate, or 2-methyl-3-ethylhexanoate.

13. The photoresist composition as claimed in claim 9, wherein:
the photosensitive polymer includes an ester group in a first repeating unit thereof, and
the protecting group is bonded to the ester group.

14. The photoresist composition as claimed in claim 13, wherein the first repeating unit has a structure such that:
the protecting group is separable from the ester group in the presence of an acid, and
the ester group forms a coordination bond with the metal element M in the presence of the acid.

15. The photoresist composition as claimed in claim 13, wherein:
the photosensitive polymer further includes a second repeating unit having a hydroxy group or a carboxyl group, and
the second repeating unit has a structure such that the hydroxy group or the carboxyl group forms a coordination bond with the metal element M in the presence of an acid.

16. The photoresist composition as claimed in claim 15, wherein the second repeating unit includes one of the following moieties, 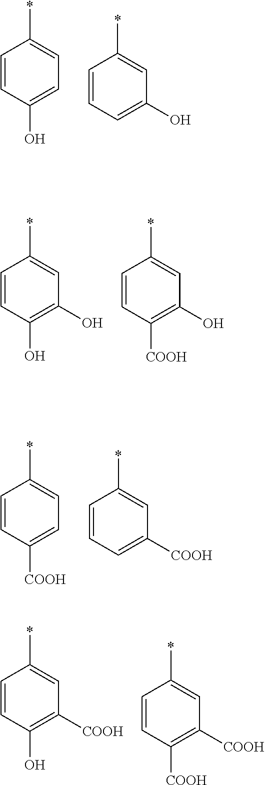
in which “*” denotes a bonding position.

17. The photoresist composition as claimed in claim 9, further comprising about 0.01 wt % to about 5 wt % of a basic quencher.

18. A photoresist composition, comprising:
a photosensitive polymer;
a photoacid generator;
a metal precursor, the metal precursor including tin (II) ethoxide, tin (IV) n-butoxide, tin (IV) tert-butoxide, tin (IV) acetate, tin (II) 2-ethylhexanoate, dibutyl tin chloride, lead (II) acetate hydrate, zinc acetate hydrate, or titanium (IV) isopropoxide;
a basic quencher; and
a solvent.

19. The photoresist composition as claimed in claim 18, wherein the metal precursor is included in the photoresist composition in an amount of about 3 wt % to about 7.5 wt %, based on a total weight of the photosensitive polymer.

20. The photoresist composition as claimed in claim 19, wherein:
the metal precursor is tin (II) 2-ethylhexanoate,
the metal precursor is included in the photoresist composition in an amount of about 4 wt % to about 6 wt %, based on the total weight of the photosensitive polymer.

21-25. (canceled)
